(19) United States
(12) Patent Application Publication
(10) Pub. No.: US 2006/0197218 A1
(43) Pub. Date: Sep. 7, 2006

(54) HIP PACKAGE STRUCTURE

(76) Inventor: Jun-Cheng Liu, Kaohsiung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,822

(22) Filed: Dec. 7, 2005

(30) Foreign Application Priority Data
Dec. 9, 2004 (TW) 93138083

(51) Int. Cl. H01L 23/34

(52) U.S. Cl. 257/706

(57) ABSTRACT

A chip package structure is provided, including a package substrate, a chip, a heat spreader, and a molding compound. The chip is disposed on a surface of the package substrate, and electrically connected thereof. The heat spreader is disposed on the surface of the package substrate, and the heat spreader includes a coating layer, a top portion and a support portion connected to the edge of the top portion. The top portion is above the chip, and the coating layer is only disposed on the surface of the top portion far away from the chip. The surface of the heat spreader uncovered by the coating layer is treated with an oxidization treatment. The support portion is in contact with the package substrate. The molding compound is disposed on the surface of the package substrate and envelopes the chip and the support portion but exposing the coating layer.

### CROSS-REFERENCE TO RELATED APPLICATION

This application claims the priority benefit of Taiwan application serial no. 93138083, filed on Dec. 9, 2004. All disclosure of the Taiwan application is incorporated herein by reference.

### BACKGROUND OF THE INVENTION

1. Field of Invention

The present invention relates to a chip package structure. More particularly, the present invention relates to a chip package structure with heat spreader.

2. Description of Related Art

In recent years, with the enhanced integration of the internal circuitry of the integrated circuit (IC) chip, the chip accordingly generates more heat. For the personal computer, all of the high integrated IC chips (such as the IC chips of the CPU or graphic chip) may generate heat. In order for the above chips to operate normally, the IC chips must be kept at a preferred work temperature to avoid declining effect or damage due to high temperature. That is, with increased heat in the IC chips, the requirement of the heat spreading system also increases, so that the current chip package structure is equipped with a heat spreader.

As mentioned above, in some chip package structure, as part of area of the heat spreader is exposed, the surface of the heat spreader is usually electroplated to meet the appearance requirement. However, as the surface of the heat spreader is electroplated, the bonding strength between the molding compound and the heat spreader decreases. In addition, as the bonding strength between the molding compound and the heat spreader is low, when temperature changes, moisture may enter the chip package structure through the interface between the molding compound and the heat spreader, reducing the reliability of the chip package structure.

### SUMMARY OF THE INVENTION

Accordingly, the present invention is directed to provide a chip package structure with good bonding strength between the heat spreader and the molding compound.

According to the above and other aspects of the present invention, the present invention provides a chip package structure, comprising: a package substrate, a chip, a heat spreader, and a molding compound. Wherein, the chip is disposed on one surface of the package substrate, and the chip is electrically connected to the package substrate. Further, the heat spreader is disposed on the surface of the package substrate. The heat spreader comprises a coating layer, a top portion and a support portion connected to the edge of the top portion. The top portion is above the chip, and the coating layer is only disposed on the surface of the top portion far away from the chip. The surface of the heat spreader uncovered by the coating layer is treated with an oxidization treatment. Furthermore, the support portion is in contact with the package substrate. Moreover, the molding compound is disposed on the surface of the package substrate and envelops the chip and the support portion of the heat spreader but exposing the coating layer thereof.

According to one preferred embodiment of the present invention, the material of the coating layer can be nichrome.

According to one preferred embodiment of the present invention, the chip package structure further comprises solder balls, disposed on another surface of the package substrate.

According to one preferred embodiment of the present invention, the chip package structure further comprises conductive wires, electrically connected between the chip and the package substrate.

According to one preferred embodiment of the present invention, the chip package structure further comprises bumps, disposed between the chip and the package structure and electrically connected between the chip and the package substrate. Moreover, the chip package structure further comprises an adhesive layer, disposed between the heat spreader and the chip.

According to the above and other aspects of the present invention, the present invention provides a chip package structure, comprising: a package substrates, a chip, a heat spreader, and a molding compound. Wherein, the chip is disposed on one surface of the package substrate, and the chip and the package substrate are electrically connected. Further, the molding compound is disposed on the surface of the package substrate and envelopes the chip. In addition, a coating layer is disposed on part of the surface of the spreader. The heat spreader is embedded in the molding compound, and the coating layer is exposed by the molding compound. The surface of the heat spreader uncovered by the coating layer is treated with an oxidization treatment.

According to one preferred embodiment of the present invention, the material of the coating layer can be nichrome.

According to one preferred embodiment of the present invention, the chip package structure further comprises solder balls, disposed on another surface of the package substrate.

According to one preferred embodiment of the present invention, the chip package structure further comprises conductive wires, electrically connected between the chip and the package substrate.

According to one preferred embodiment of the present invention, the chip package structure further comprises bumps, disposed between the chip and the package structure and electrically connected between the chip and the package substrate. Moreover, the chip package structure further comprises an adhesive layer, disposed between the heat spreader and the chip.

Based on the mentioned above, as the coating layer is disposed on only a partial surface of the heat spreader and the coating layer is exposed by the molding compound, the chip package structure of the present invention not only has good reliability, but also can meet the appearance requirement. Furthermore, as the coating layer is disposed only on a partial surface of the heat spreader, the heat spreader has lower cost.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a chip package structure according to one preferred embodiment of the present invention.

FIG. 2 is a schematic diagram of a chip package structure according to another preferred embodiment of the present invention.

FIG. 3 is a schematic diagram of a chip package structure according to another preferred embodiment of the present invention.

FIG. 4 is a schematic diagram of a chip package structure according to another preferred embodiment of the present invention.

### DESCRIPTION OF EMBODIMENTS

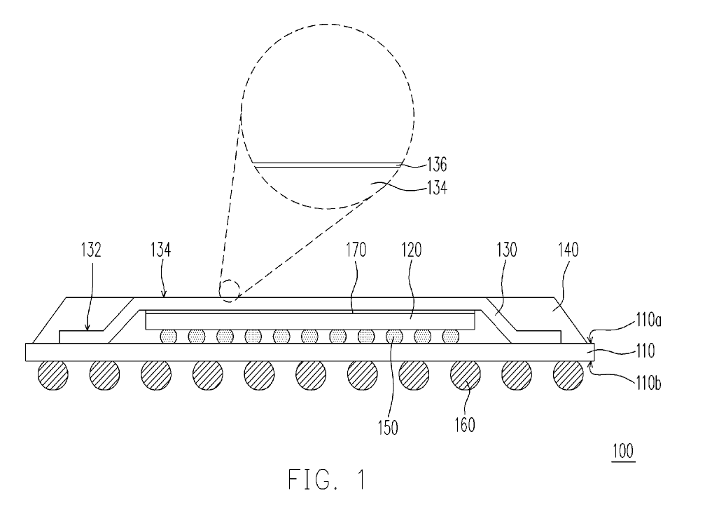

FIG. 1 is a schematic diagram of a chip package structure according to one preferred embodiment of the present invention. Referring to FIG. 1, the chip package structure 100 comprises a package substrate 110, a chip 120, a heat spreader 130, a molding compound 140, and bumps 150. Wherein, the chip 120 is disposed on one surface 110a of the package substrate 110, and the bumps 1 50 are disposed between the package substrate 110 and the chip 120. And, the chip 120 is electrically connected to the package substrate 110 through the bumps 150. That is, the chip package structure 100 is a flip chip package structure. Moreover, the bumps 150 can be gold bumps, solder bump or bumps of other conductive materials.

The heat spreader 130 is disposed on the surface 110a of the package substrate 110, and the heat spreader 1 30 comprises a support portion 132, a top portion 134, and a coating layer 136, wherein the top portion 134 is above the chip 120, and the coating layer 136 is disposed only on the surface (as shown in the enlarged area) of the top portion 134 far away from the chip 120. Furthermore, the support portion 132 is connected to the edge of the top portion 134, and the support portion 132 is in contact with the package substrate 110. Moreover, the material of the heat spreader 130 can be copper, or other materials with good thermal conductivity, and the material of the coating layer 136 can be nichrome or other anti-oxidation and anti-corrosion metals or alloys.

Refer to FIG. 1. The molding compound 140 is disposed on the surface 110a of the package substrate 110, and envelopes the chip 120 and the support portion 132 of the heat spreader 130 but exposing the coating layer 136 thereof. Moreover, the material of the molding compound 140 can be epoxy or other plastic with low hygroscopicity and high anti-corrosion. In addition, the chip package structure 100 further comprises solder balls 160 and an adhesion layer 170. Wherein the adhesion layer 170 is disposed between the heat spreader 130 and the chip 120, and the preferred adhesion layer 170 can be thermal paste which can improve the heat spreading efficiency of the chip package structure. Moreover, the solder balls 160 are disposed on another surface 110b of the package substrate 110, and electrically connected to the chip 120 through the package substrate 110 and the bumps 150. Note that, the solder balls 160 are electrically connected to a circuit board (not shown); however, the present invention is not limit to the solder balls 160, and pins or other types of joints can be used as well.

As mentioned above, as the coating layer 136 is disposed only on part of the surface of the heat spreader 130, and the molding compound 140 exposes the coating layer 136, therefore, the bonding strength between the molding compound 140 and the heat spreader 130 will be improved. That is, the chip package structure 100 not only has good reliability, but also can meet the appearance requirement. Furthermore, as the coating layer 136 is disposed only on part of the surface of the heat spreader 130, the material cost of the heat spreader 130 can be reduced. Note that, the surface of the heat spreader 130 uncovered by the coating layer 136 may further be oxidized, and the heat spreader 130 has large surface area (the surface is villiform) after an oxidation treatment, so that the bonding strength between the molding compound 140 and the heat spreader 130 can be further improved.

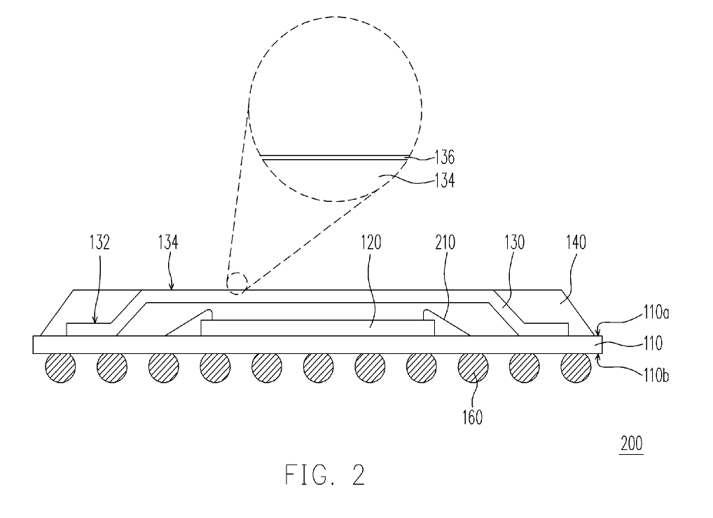

FIG. 2 is a schematic diagram of a chip package structure according to another preferred embodiment of the present invention. Referring to FIG. 2, FIG. 2 is similar to FIG. 1, and the difference is that in the chip package structure 200 of the embodiment, the chip 120 is electrically connected to the package substrate 110 through conductive wires 210. That is, the chip package structure 200 is a wire bonding package structure. Moreover, the material of the conductive wires 210 can be copper, gold, or other conductive materials. In addition, the present invention is not limited to solder ball 160, so that pins or other types of joints can also be used for electrical connection. Moreover, as mentioned above, in order to improve the bonding strength between the heat spreader 130 and the molding compound 140, the surface of the heat spreader 130 uncovered by the coating layer 136 may further be oxidized.

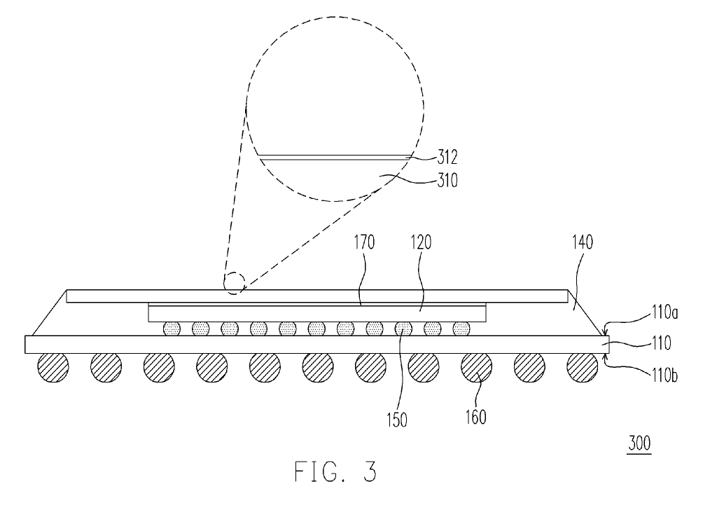

FIG. 3 is a schematic diagram of a chip package structure according to another preferred embodiment of the present invention. Referring to FIG. 3, FIG. 3 is similar to FIG. 1, and the difference is that in the chip package structure 300 of the embodiment, a coating layer 312 is disposed on part of the surface of the heat spreader 310, and the heat spreader 310 is embedded in the molding compound 140, and the molding compound 140 exposes the coating layer 312. That is, the present invention does not limit the type of the heat spreader 310, and the coating layer 312 is disposed only on the exposed portion of the heat spreader 310. Moreover, as mentioned above, in order to improve the bonding strength between the heat spreader 310 and the molding compound 140, the surface of the heat spreader 310 uncovered by the coating layer 312, may further be oxidized.

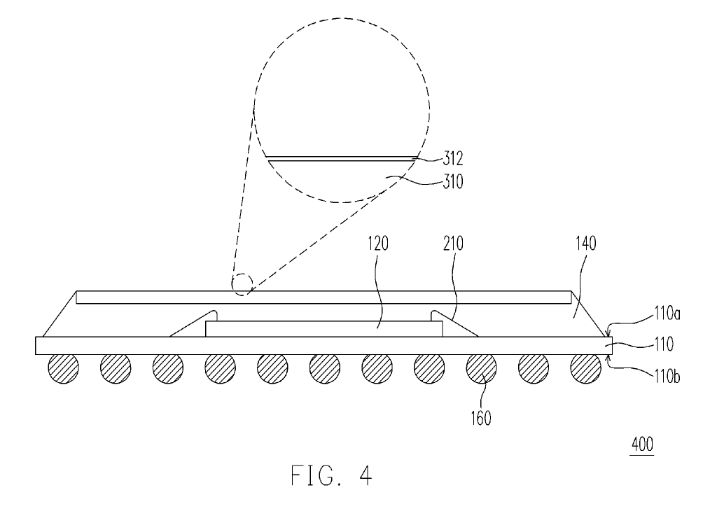

FIG. 4 is a schematic diagram of a chip package structure according to another preferred embodiment of the present invention. Referring to FIG. 4, FIG. 4 is similar to FIG. 3, and the difference is that in the chip package structure 400 of the embodiment, the chip 120 is electrically connected to the package substrate 110 through conductive wires 210. That is, the chip package structure 400 is a wire bonding package structure. Moreover, the surface of the heat spreader 310 uncovered by the coating layer 312 may further be oxidized.

In summary, the chip package structure of the present invention has at least the following advantages:

First, compared with the conventional technology, as the coating layer is disposed only on part of the surface of the heat spreader, and the molding compound exposes the coating layer, the bonding strength between the molding compound and the heat spreader can be improved. That is, the chip package structure of the present invention not only has good reliability, but can also meet the appearance requirement.

Second, compared with the conventional technology, as the coating layer is disposed only on part of the surface of the heat spreader, the heat spreader has low material cost. Moreover, the surface of the heat spreader uncovered by the coating layer may further be oxidized, so that the bonding strength between the molding compound and the heat spreader is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a package substrate;
a chip, disposed on the surface of the package substrate, the chip being electrically connected to the package substrate;
a heat spreader, disposed on the surface of the package substrate, the heat spreader comprising a coating layer, a top portion and a support portion connected to the edge of the top portion, wherein the top portion is above the chip, and the coating layer is only disposed on the surface of the top portion far away form the chip, and the support portion is in contact with the package substrate, and the surface of the heat spreader uncovered by the coating layer is treated with an oxidization treatment; and
a molding compound, disposed on the surface of the package substrate, the molding compound enveloping the chip and the support portion of the heat spreader but exposing the coating layer thereof.

2. The chip package structure as claimed in claim 1, wherein the material of the coating layer includes nichrome.

3. The chip package structure as claimed in claim 1, further comprising a plurality of solder balls, disposed on another surface of the package substrate.

4. The chip package structure as claimed in claim 1, further comprising a plurality of conductive wires, electrically connected between the chip and the package substrate.

5. The chip package structure as claimed in claim 1, further comprising a plurality of bumps, disposed between the chip and the package structure and electrically connected between the chip and the package substrate.

6. The chip package structure as claimed in claim 5, further comprising an adhesive layer, disposed between the heat spreader and the chip.

7. A chip package structure, comprising:
a package substrate,
a chip, disposed on the surface of one of the package substrates, the chip being electrically connected to the package substrate;
a molding compound, disposed on the surface of the package substrate and enveloping the chip; and
a heat spreader, having a coating layer disposed on part of the surface thereof, the heat spreader being embedded in the molding compound, and the coating layer being exposed by the molding compound, wherein the surface of the heat spreader uncovered by the coating layer is treated with an oxidization treatment.

8. The chip package structure as claimed in claim 7, wherein the material of the coating layer includes nichrome.

9. The chip package structure as claimed in claim 7, further comprising a plurality of solder balls, disposed on another surface of the package substrate.

10. The chip package structure as claimed in claim 7, further comprising a plurality of conductive wires, electrically connected between the chip and the package substrate.

11. The chip package structure as claimed in claim 7, further comprising a plurality of bumps, disposed between the chip and the package structure and electrically connected between the chip and the package substrate.

12. The chip package structure as claimed in claim 7, further comprising an adhesive layer, disposed between the heat spreader and the chip.
